(19) United States
(12) Patent Application Publication
(10) Pub. No.: US 2026/0047088 A1
(43) Pub. Date: Feb. 12, 2026

(54) SEMICONDUCTOR STRUCTURE AND MANUFACTURING METHOD THEREOF

(71) Applicant: United Microelectronics Corp., Hsinchu (TW)

(72) Inventor: Hsuan Kai Wang, Tainan City (TW)

(73) Assignee: United Microelectronics Corp., Hsinchu (TW)

(21) Appl. No.: 18/813,057

(22) Filed: Aug. 23, 2024

(30) Foreign Application Priority Data
Aug. 9, 2024 (TW) 113129894

(51) Int. Cl. H10B 41/30; H01L 21/28; H01L 29/423; H01L 29/66; H01L 29/788; H10B 41/42

(52) U.S. Cl. CPC H10B 41/30; H10B 41/42; H10D 30/0411; H10D 30/683; H10D 30/6892; H10D 64/017; H10D 64/035

(57) ABSTRACT

A semiconductor structure includes a substrate and a memory element. The memory element is disposed on the substrate and includes a floating gate, a tunnel dielectric layer, a control gate structure, an inter-gate oxide layer, an erase gate, and a word line. The floating gate is disposed on the substrate. The tunnel dielectric layer is disposed between the floating gate and the substrate. The control gate structure is disposed on the floating gate. The control gate structure includes a high-k dielectric layer and a metal gate, and a width of a top portion of the control gate structure is greater than a width of a bottom portion of the control gate structure. The inter-gate oxide layer is disposed between the floating gate and the control gate structure. The erase gate is disposed on one side of the floating gate. The word line is disposed on the other side of the floating gate. A manufacturing method of a semiconductor structure is also provided.

### CROSS-REFERENCE TO RELATED APPLICATION

This application claims the priority benefit of Taiwan application serial no. 113129894, filed on Aug. 9, 2024. The entirety of the above-mentioned patent application is hereby incorporated by reference herein and made a part of this specification.

### BACKGROUND

### Technical Field

The disclosure relates to a semiconductor structure and a manufacturing method thereof, and more particularly, to an embedded flash and a manufacturing method thereof.

Description of Related Art

In a conventional forming method of an embedded flash (E-flash), it is difficult to form a control gate using a high-k metal gate (HKMG) process. Therefore, in the above forming method, a relatively large doped region is disposed in a substrate to replace a function of the control gate. However, this will result in the eventually formed embedded flash having poor writing efficiency.

### SUMMARY

The disclosure provides a semiconductor structure with relatively good writing efficiency.

Some embodiments of the disclosure provide a semiconductor structure including a substrate and a memory element. The memory element is disposed on the substrate and includes a floating gate, a tunnel dielectric layer, a control gate structure, an inter-gate oxide layer, an erase gate, and a word line. The floating gate is disposed on the substrate. The tunnel dielectric layer is disposed between the floating gate and the substrate. The control gate structure is disposed on the floating gate. The control gate structure includes a high-k dielectric layer and a metal gate, and a width of a top portion of the control gate structure is greater than a width of a bottom portion of the control gate structure. The inter-gate oxide layer is disposed between the floating gate and the control gate structure. The erase gate is disposed on one side of the floating gate. The word line is disposed on the other side of the floating gate.

The disclosure provides a manufacturing method of a semiconductor structure, and the manufactured semiconductor structure has relatively good writing efficiency.

Other embodiments of the disclosure provide a manufacturing method of a semiconductor structure, including the following steps. A memory material layer is formed on a substrate. The memory material layer sequentially includes a floating gate, an erase gate, a first nitride layer, a first oxide layer, a second nitride layer, and a second oxide layer. A first recess is formed in the memory material layer. The first recess exposes a portion of the first nitride layer.

A second recess is formed in the memory material layer. The second recess overlaps the first recess to form an opening, and the second recess exposes a portion of the floating gate. An inter-gate oxide layer is formed in the opening. A dummy gate structure including a high-k dielectric layer is formed in the opening. The dummy gate structure is replaced with a control gate structure including a metal gate to form a memory element. A width of a top portion of the control gate structure is greater than a width of a bottom portion of the control gate structure.

Based on the above, the disclosure provides the novel semiconductor structure and the manufacturing method thereof. By forming the control gate structure including the high-k dielectric layer and the metal gate in the memory element, compared to the conventional embedded flash, the writing efficiency of the memory element in the disclosure may be increased.

### BRIEF DESCRIPTION OF THE DRAWINGS

FIGS. 1A to 1F are schematic views of a flow process of a manufacturing method of a semiconductor structure according to an embodiment of the disclosure.

FIG. 2A is a schematic partial cross-sectional view of a semiconductor structure according to an embodiment of the disclosure.

FIG. 2B is a schematic partial cross-sectional view of a control gate structure according to an embodiment of the disclosure.

### DETAILED DESCRIPTION OF DISCLOSED EMBODIMENTS

Examples are provided below with reference to the accompanying drawings to describe the disclosure in detail, but the provided examples are not intended to limit the scope of the disclosure. In addition, the drawings of the disclosure are drawn only for the purpose of description, and specific elements in the drawings are not drawn according to actual scale. In order to make it easy for the reader to understand, the same elements in the following description will be denoted by the same reference numerals for recognition.

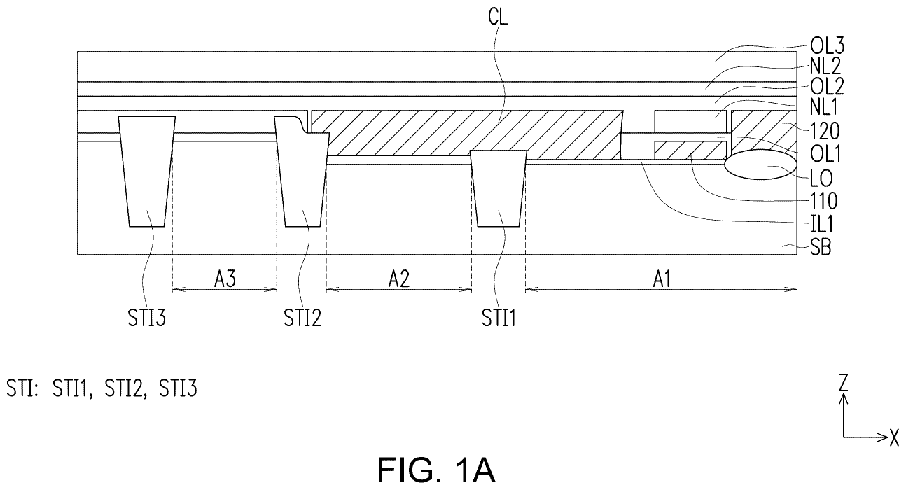

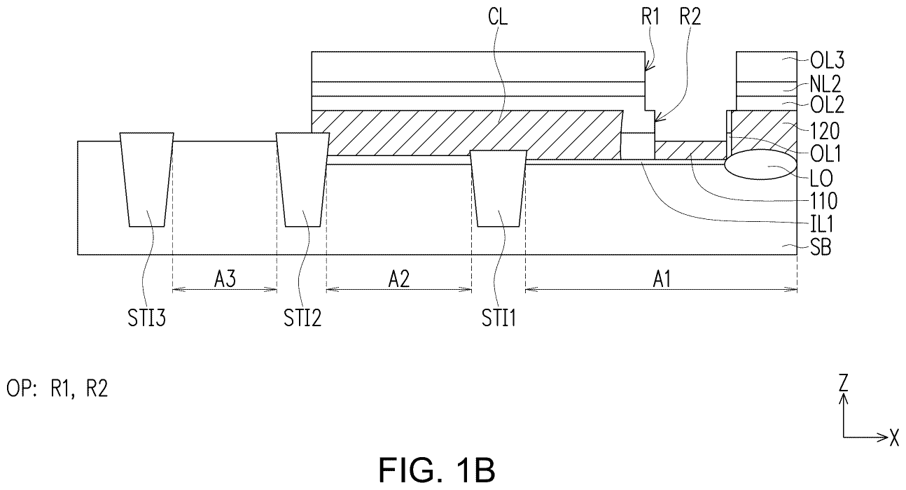

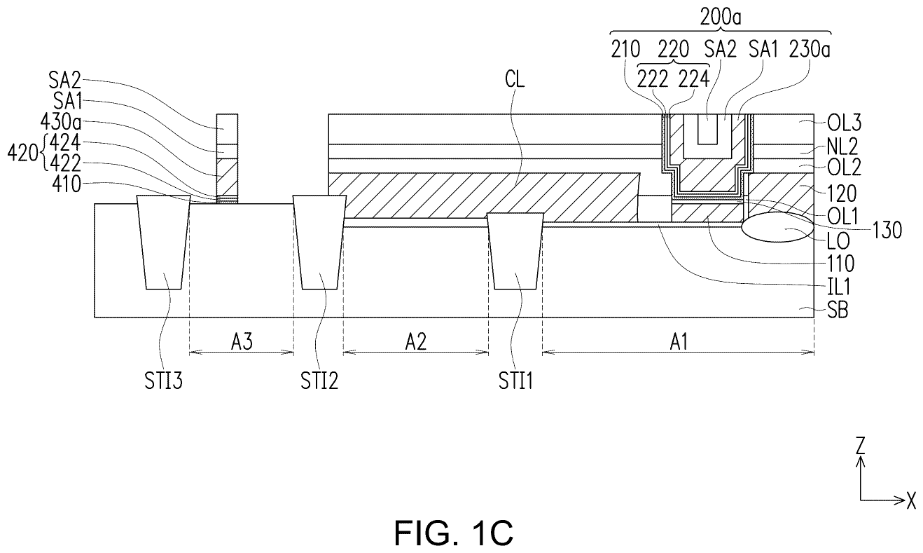

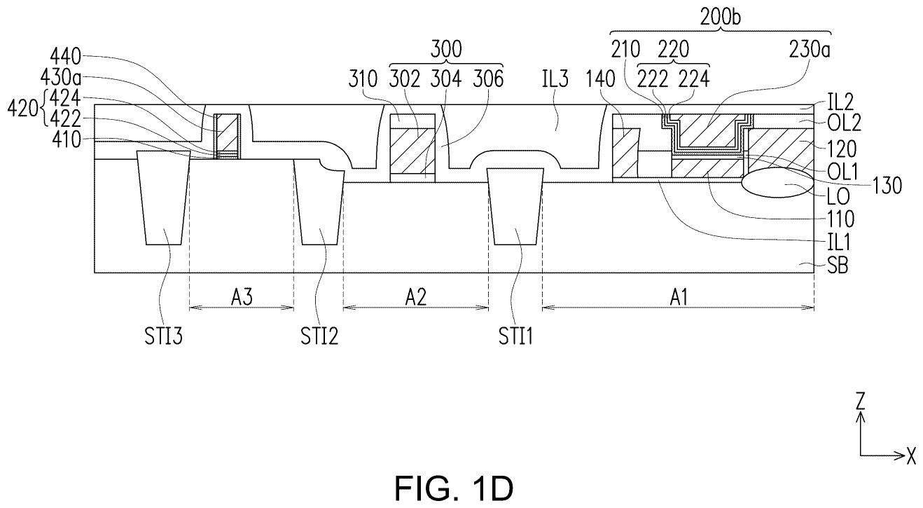

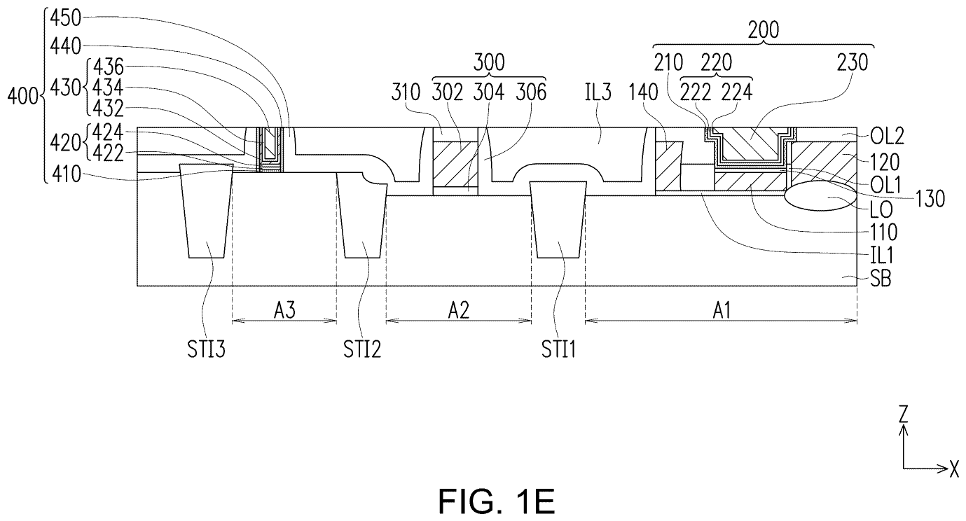

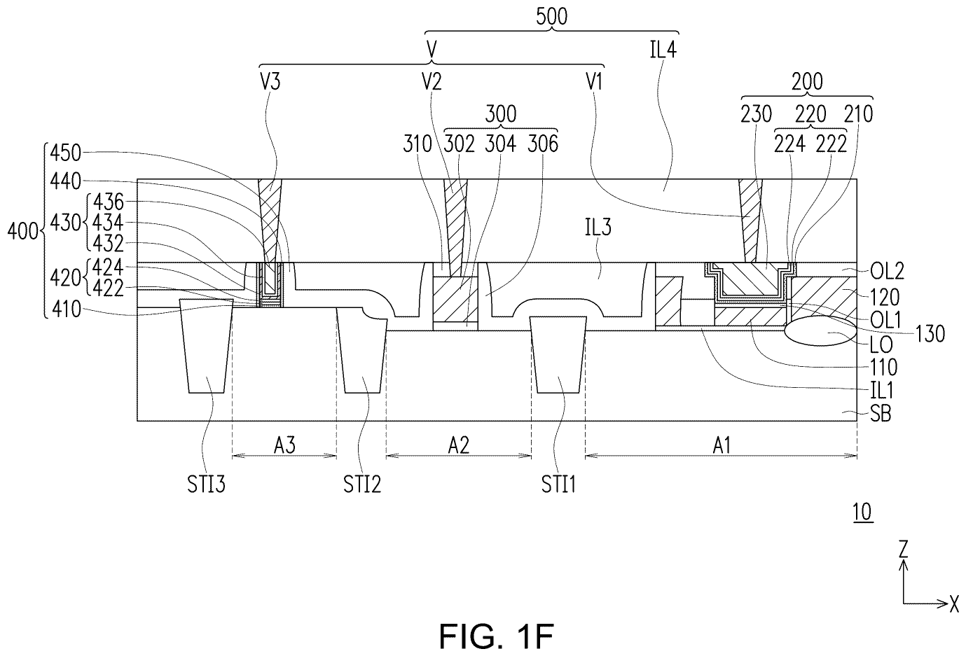

FIGS. 1A to 1F are schematic views of a flow process of a manufacturing method of a semiconductor structure according to the first embodiment of the disclosure.

Referring to FIGS. 1A to 1F, in this embodiment, the following steps may be performed to form a semiconductor structure 10, but the disclosure is not limited thereto.

The step (1) is performed. A memory material layer is formed on a substrate SB.

Referring to FIG. 1A, in some embodiments, the substrate SB may be a semiconductor substrate, but the disclosure is not limited thereto. A material of the substrate SB may, for example, include an elemental semiconductor, a compound semiconductor, an alloy semiconductor, or other suitable materials. For example, the material of the substrate SB may include silicon, germanium, indium antimonide, indium arsenide, indium phosphide, gallium nitride, gallium arsenide, gallium antimonide, lead telluride, or a combination thereof. In other embodiments, the substrate SB may be a silicon on insulator (SOI) substrate.

In this embodiment, the substrate SB includes a memory element area A1, a high voltage element area A2, and a logic element area A3. The memory material layer is formed in the memory element area Al of the substrate SB. It is worth noting that before the memory material layer is formed on the substrate SB, a dielectric layer IL1, a local oxidation of silicon (LOCOS) LO, and a shallow trench isolation structure STI may be formed on the substrate SB. In this embodiment, the dielectric layer IL1 located in the memory element area A1 may be formed into a tunnel dielectric layer after subsequent processes, and the dielectric layer IL1 located in the high voltage element area A2 may be formed into a gate dielectric layer after the subsequent processes, which will be described in detail in the following embodiments. The local oxidation of silicon LO is, for example, disposed in the memory element area A1 and adjacent to the dielectric layer IL1. In some embodiments, the local oxidation of silicon LO may be formed by performing a thermal oxidation process, but the disclosure is not limited thereto. The shallow trench isolation structure STI includes, for example, a shallow trench isolation structure STI1, a shallow trench isolation structure STI2, and a shallow trench isolation structure STI3. The shallow trench isolation structure STI1 is, for example, used to separate the memory element area A1 and the high voltage element area A2. The shallow trench isolation structure STI2 is, for example, used to separate the high voltage device area A2 and the logic element area A3. The shallow trench isolation structure STI3 is, for example, used to separate the logic element area A3 and another element area (not shown). In some embodiments, the shallow trench isolation structure STI may be formed by first performing an etching process to form multiple grooves in the substrate SB, and then performing a chemical vapor deposition process to form an insulation material in the grooves. However, the disclosure is not limited thereto.

The memory material layer includes, for example, a floating gate 110, an erase gate 120, a first oxide layer OL1, a first nitride layer NL1, a second oxide layer OL2, a second nitride NL2 layer, and a third oxide layer OL3. However, the disclosure is not limited thereto.

The floating gate 110 is, for example, disposed on the dielectric layer IL1. In some embodiments, a material of the floating gate 110 includes polysilicon. However, the disclosure is not limited thereto.

The erase gate 120 is, for example, disposed on one side of the floating gate 110. In some embodiments, a material of the erase gate 120 includes polysilicon. However, the disclosure is not limited thereto.

It is worth noting that the memory material layer may further include, for example, a conductive material layer CL located in the memory element area A1 and the high voltage element area A2. The conductive material layer CL is, for example, disposed on the dielectric layer IL1. The conductive material layer CL located in the memory element area A1 may be formed into a word line material layer after the subsequent processes, and the conductive material layer CL located in the high voltage element area A2 may be formed into a gate material layer after the subsequent processes. In some embodiments, a material of the conductive material layer CL includes polysilicon, but the disclosure is not limited thereto. In other embodiments, the conductive material layer CL, the floating gate 110, and the erase gate 120 may belong to the same layer.

The first oxide layer OL1 is, for example, disposed on the floating gate 110. In this

embodiment, the first oxide layer OL1 covers the floating gate 110. In some embodiments, a material of the first oxide layer OL1 includes silicon oxide, but the disclosure is not limited thereto.

The first nitride layer NL1 is, for example, disposed on the first oxide layer OL1. In some embodiments, a material of the first nitride layer NL1 includes silicon nitride, but the disclosure is not limited thereto. It is worth noting that the first nitride layer NL1 is also disposed in the logic element area A3 and covers the dielectric layer IL1, but the disclosure is not limited thereto.

The second oxide layer OL2 is, for example, disposed on the first nitride layer NL1. In this embodiment, the second oxide layer OL2 covers the first nitride layer NL1 and the erase gate 120. In some embodiments, a material of the second oxide layer OL2 includes silicon oxide, but the disclosure is not limited thereto. It is worth noting that the second oxide layer OL2 is also disposed in the high voltage element area A2 and the logic element area A3, but the disclosure is not limited thereto.

The second nitride layer NL2 is, for example, disposed on the second oxide layer OL2. In some embodiments, a material of the second nitride layer NL2 includes silicon nitride, but the disclosure is not limited thereto. It is worth noting that the second nitride layer NL2 is also disposed in the high voltage element area A2 and the logic element area A3, but the disclosure is not limited thereto.

The third oxide layer OL3 is, for example, disposed on the second nitride layer NL2. In some embodiments, a material of the third oxide layer OL3 includes silicon oxide, but the disclosure is not limited thereto. It is worth noting that the third oxide layer OL3 is also disposed in the high voltage element area A2 and the logic element area A3, but the disclosure is not limited thereto.

The step (2) is performed. A first recess R1 is formed in the memory material layer.

Referring to FIG. 1B, in some embodiments, the etching process may be performed to form the first recess R1 in the memory material layer. In this embodiment, the first recess R1 exposes a portion of the first nitride layer NL1. In detail, the above etching process may be performed to sequentially remove a portion of the third oxide layer OL3, the second nitride layer NL2, and the second oxide layer OL2. The material of the second oxide layer OL2 and the material of the first nitride layer NL1 have different etching selectivity, so that the first nitride layer NL1 may be used as an etch stop layer in this etching process.

It is worth noting that in the step of forming the first recess R1, the third oxide layer OL3, the second nitride layer NL2, and the second oxide layer OL2 located in the logic element area A3 may also be removed at the same time, but the disclosure is not limited thereto.

The step (3) is performed. A second recess R2 is formed in the memory material layer.

Continuing to refer to FIG. 1B, in some embodiments, the etching process may be performed to form the second recess R2 in the memory material layer. In this embodiment, the second recess R2 and the first recess R1 overlap in a normal direction Z of the substrate SB to form an opening OP. In detail, the second recess R2 is formed by performing the etching process on the first nitride layer NL1 exposed by the first recess R1. In this embodiment, a width of the second recess R2 in a direction X is less than a width of the first recess R1 in the direction X. In this embodiment, the second recess R2 exposes a portion of the first oxide layer OL1. In detail, the above etching process may be performed to remove the first nitride layer NL1. The material of the first nitride layer NL1 and the material of the first oxide layer OL1 have different etching selectivity, so that the first oxide layer OLI may be used as an etch stop layer in this etching process.

The step (4) is performed. An inter-gate oxide layer 130 is formed in the opening OP.

Referring to FIG. 1C, in some embodiments, the inter-gate oxide layer 130 may be formed on the floating gate 110 by performing a suitable deposition process, but the disclosure is not limited thereto. The inter-gate oxide layer 130 may include a composite structure, for example.

In this embodiment, the inter-gate oxide layer 130 includes three dielectric layers stacked sequentially. For example, the inter-gate oxide layer 130 may include an oxide-nitride-oxide (ONO) composite layer, but the disclosure is not limited thereto. In other embodiments, the inter-gate oxide layer 130 may include a single-layer structure, and an included material thereof may be silicon oxide.

The step (5) is performed. A dummy gate structure 200a is formed in the opening OP.

Continuing to refer to FIG. 1C, in some embodiments, a method of forming the dummy gate structure 200a in the opening OP includes the following steps, but the disclosure is not limited thereto.

First, a high-k dielectric layer 210 is formed on a sidewall of the opening OP. In some

embodiments, the high-k dielectric layer 210 may be formed by performing the suitable deposition process, but the disclosure is not limited thereto. A material of the high-k dielectric layer 210 may include, for example, hafnium oxide (HfO₂), aluminum oxide (Al₂O₃), lanthanum oxide (La₂O₃), tantalum oxide (Ta₂O₅), yttrium oxide (Y₂O₃), zirconium oxide (ZrO₂), or other suitable materials with high dielectric constant. In this embodiment, the material of the high-k dielectric layer 210 is hafnium oxide, but the disclosure is not limited thereto. It is worth noting that in this embodiment, in the step of forming the high-k dielectric layer 210, a high-k dielectric layer 410 is also formed in the logic element area A3, but the disclosure is not limited thereto. In addition, before the high-k dielectric layer 410 is formed, a buffer layer (not shown) may first be formed in the logic element area A3 for the purpose of buffering the high-k dielectric layer 410 and the substrate SB.

Next, a bottom barrier layer 220 is formed on the high-k dielectric layer 210. In some embodiments, the bottom barrier layer 220 may be formed by performing the suitable deposition process, but the disclosure is not limited thereto. A material of the bottom barrier layer 220 may include, for example, titanium (Ti), titanium nitride (TiN), tantalum nitride (TaN), or a combination thereof. In this embodiment, the bottom barrier layer 220 is a multi-layer structure. In detail, the bottom barrier layer 220 may include a first bottom barrier layer 222 and a second bottom barrier layer 224. A material of the first bottom barrier layer 222 is titanium nitride, and a material of the second bottom barrier layer 224 is tantalum nitride. However, the disclosure is not limited thereto. It is worth noting that in this embodiment, in the step of forming the bottom barrier layer 220, a bottom barrier layer 420 including a first bottom barrier layer 422 and a second bottom barrier layer 424 is also formed in the logic element area A3 at the same time. However, the disclosure is not limited thereto.

After that, a dummy gate 230a is formed on the bottom barrier layer 220. In some embodiments, the dummy gate 230a may be formed by performing the suitable deposition process, but the disclosure is not limited thereto. A material of the dummy gate 230a may include polysilicon, for example. It is worth noting that in this embodiment, in the step of forming the dummy gate 230a, a dummy gate 430a is also formed in the logic element area A3 at the same time, but the disclosure is not limited thereto.

In some embodiments, it may further include removing a portion of the dummy gate 230a to form a recess. A bottom of the recess is substantially flushed with a bottom of the second nitride layer NL2. After that, a first sacrificial layer SA1 and a second sacrificial layer SA2 are sequentially formed in the recess. A material of the first sacrificial layer SA1 is silicon nitride, and a material of the second sacrificial layer SA2 is silicon oxide. It is worth noting that in this embodiment, the first sacrificial layer SA1 and the second sacrificial layer SA2 are also formed in the logic element area A3 at the same time, but the disclosure is not limited thereto.

So far, fabrication of the dummy gate structure 200a has been completed. Although a manufacturing method of the dummy gate structure 200a in this embodiment is described by taking the above method as an example, the manufacturing method of the dummy gate structure in the disclosure is not limited thereto.

The step (6) is performed. A portion of the dummy gate structure 200a is removed to form a dummy gate structure 200b.

Referring to FIG. 1D, in some embodiments, the etching process may be performed to remove a portion of the high-k dielectric layer 210, a portion of the bottom barrier layer 220, and the portion of the dummy gate 230a to form the dummy gate structure 200b. It is worth noting that the first sacrificial layer SAI and the second sacrificial layer SA2 are also removed in the etching process. In addition, in this embodiment, the remaining second nitride layer NL2 and third oxide layer OL3 are also removed in the etching process, and a portion of the second oxide layer OL2 is exposed.

It is worth noting that after the dummy gate structure 200b is formed, subsequent steps are further included.

First, a patterning process is performed on the second oxide layer OL2, the conductive material layer CL, and the dielectric layer IL1 to form a word line 140 and a tunnel dielectric layer 150 in the memory element area A1. The word line 140 is a portion of the conductive material layer CL, and the tunnel dielectric layer 150 is a portion of the dielectric layer IL1. It is worth noting that a high voltage element 300 is also formed in the high voltage element area A2 while the above patterning process is performed. In detail, the high voltage element 300 includes, for example, a gate 302, a gate oxide layer 304, and a spacer 306. The gate 302 is a portion of the conductive material layer CL. The gate oxide layer 304 is a portion of the dielectric layer IL1. The spacer 306 is a portion of the dielectric layer IL2. In addition, the second oxide layer OL2 after the above patterning process may be formed into a dielectric layer 310.

Next, a sidewall 440 may be formed in the logic element area A3 by performing the suitable deposition process. The sidewall 440 is disposed on both sides of the high-k dielectric layer 410, the bottom barrier layer 420, and the dummy gate 430a.

After that, the conformal dielectric layer IL2 is formed in the memory element area A1,

the high voltage element area A2, and the logic element area A3 by performing the suitable deposition process. In some embodiments, a material of the dielectric layer IL2 includes silicon nitride, but the disclosure is not limited thereto. The dielectric layer IL2 may, for example, serve as a spacer for subsequent elements, which will be described in detail in the following embodiments.

Then, a dielectric layer IL3 is formed by performing the suitable deposition process or a spin coating process. In this embodiment, the dielectric layer IL3 exposes a portion of the dielectric layer IL2 located in the memory element area A1, the high voltage element area A2, and the logic element area A3 respectively, and has a top surface substantially flushed with the dielectric layers IL2. In some embodiments, a material of dielectric layer IL3 includes silicon oxide, but the disclosure is not limited thereto.

The step (7) is performed. The dummy gate structure 200b is replaced with a control gate structure 200 to form a memory element 100.

Referring to FIG. 1E, in some embodiments, a method of replacing the dummy gate structure 200b with the control gate structure 200 includes the following steps, but the disclosure is not limited thereto.

First, a planarization process is performed to remove a portion of the dielectric layer IL3 and a portion of the dielectric layer IL2 to expose the dummy gate 230a.

Next, a replacement metal gate (RMG) process is performed to replace the dummy gate 230a with a metal gate 230. In this embodiment, the metal gate 230 sequentially includes a work-function metal layer 232, a top barrier layer 234, and a low resistance material layer 236, but the disclosure is not limited thereto. A material of the work-function metal layer 232 includes, for example, binary composite metal. For example, the material of the work-function metal layer 232 may include titanium aluminum (TiAl), zirconium aluminum (ZrAl), tungsten aluminum (WAl), tantalum aluminum (TaAl), hafnium aluminum (HfAl), or other suitable composite metal. In this embodiment, the material of the work-function metal layer 232 is titanium aluminum, but the disclosure is not limited thereto. A material of the top barrier layer 234 may include, for example, titanium (Ti), titanium nitride (TiN), tantalum nitride (TaN), or a combination thereof. In this embodiment, the material of the top barrier layer 234 is a combination of titanium and titanium nitride, but the disclosure is not limited thereto. A material of the low resistance material layer 236 may include, for example, aluminum (Al), tungsten (W), copper (Cu), or a combination thereof. In this embodiment, the material of the low resistance material layer 236 is aluminum, but the disclosure is not limited thereto.

So far, fabrication of replacing the dummy gate structure 200b with the control gate structure 200 has been completed. Although a manufacturing method of replacing the dummy gate structure 200b with the control gate structure 200 in this embodiment is described by taking the above method as an example, the manufacturing method of replacing the dummy gate structure with the control gate structure in the disclosure is not limited thereto.

It is worth noting that the dummy gate 430a located in the logic element area A3 is also replaced with a metal gate 430 while the above replacement metal gate process is performed, so as to form a logic element 400. In detail, the metal gate 430 may sequentially include, for example, a work-function metal layer 432, a top barrier layer 434, and a low resistance material layer 436, but the disclosure is not limited thereto.

The step (8) is performed. An interconnection structure 500 is formed on the substrate SB. The interconnection structure 500 is electrically connected to the memory element 100, the high voltage element 300, and the logic element 400.

Referring to FIG. 1F, in this embodiment, the interconnection structure 500 includes a dielectric layer IL4 and multiple conductive vias V.

In some embodiments, the dielectric layer IL4 may be formed by performing the chemical vapor deposition process, the spin coating process, or other suitable processes, but the disclosure is not limited thereto. A material of the dielectric layer IL4 may be, for example, silicon oxide, silicon nitride, silicon oxynitride, polyimide, or other suitable materials, and the disclosure is not limited thereto.

The conductive vias V are, for example, disposed in the dielectric layer IL4, and each, for example, penetrates through the dielectric layer IL4. In some embodiments, the conductive vias V may be formed by performing a physical vapor deposition process, the chemical vapor deposition process, an electroplating process, or other suitable processes, but the disclosure is not limited thereto. In this embodiment, the conductive vias V include a conductive via VI, a conductive via V2, and a conductive via V3. The conductive via V1 is, for example, electrically connected to the control gate structure 200 of the memory element 100. The conductive via V2 further penetrates through the dielectric layer 310, for example, and is electrically connected to the gate 302 of the high voltage element 300, for example. The conductive via V3 is, for example, electrically connected to the metal gate 430 of the logic element 400. Materials of the conductive vias V may, for example, include suitable conductive materials. For example, the materials of the conductive vias V may include copper, titanium, tungsten, tantalum, titanium nitride, tantalum nitride, polysilicon, or a combination thereof, but the disclosure is not limited thereto.

So far, a manufacturing method of the semiconductor structure 10 in this embodiment has been completed, but the manufacturing method of the semiconductor structure 10 provided in the disclosure is not limited thereto. In this embodiment, the semiconductor structure 10 includes the memory element 100, which is an embedded flash (E-flash). By forming the control gate structure 200, writing efficiency of the memory element 100 may be relatively increased.

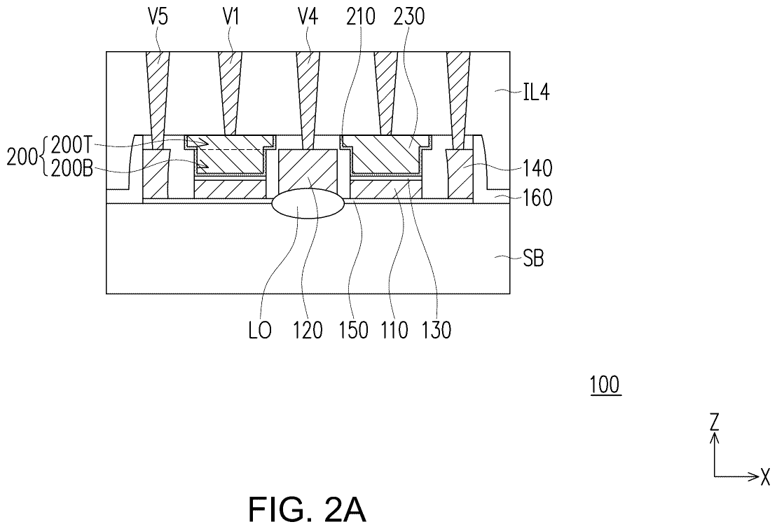

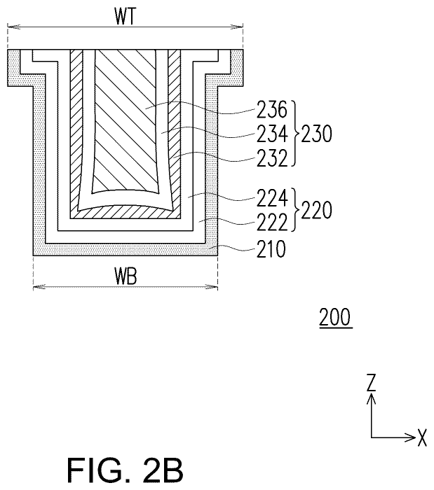

FIG. 2A is a schematic partial cross-sectional view of a semiconductor structure according to an embodiment of the disclosure. FIG. 2B is a schematic partial cross-sectional view of a control gate structure according to an embodiment of the disclosure. A structure of the semiconductor structure 10 in this embodiment will be briefly introduced below with reference to FIGS. 1F, 2A, and 2B, but the disclosure is not limited thereto.

Referring to FIGS. 1F and 2A, the semiconductor structure 10 in this embodiment includes the substrate SB and the memory element 100.

The substrate SB is, for example, a silicon substrate, but the disclosure is not limited thereto. In this embodiment, the substrate SB includes the memory element area A1, the high voltage element area A2, and the logic element area A3, and the high voltage element area A2 is located between the memory element area A1 and the logic element area A3 in the direction X. However, the disclosure is not limited thereto. For the rest of introduction about the substrate SB, reference may be made to the above embodiment, which will not be repeated in the following. The memory element 100 is, for example, disposed on the substrate SB and located in

the memory element area A1 of the substrate SB. The memory element 100 is, for example, the embedded flash (E-flash). In this embodiment, the memory element 100 includes the floating gate 110, the tunnel dielectric layer 150, the control gate structure 200, the inter-gate oxide layer 130, the erase gate 120, and the word line 140.

The floating gate 110 is, for example, disposed on the substrate SB. The floating gate 110 may, for example, be used to store hot electrons and have a function of storing data. For the rest of introduction about the floating gate 110, reference may be made to the above embodiment, which will not be repeated in the following.

The tunnel dielectric layer 150 is, for example, disposed on the substrate SB, and is, for example, located between the floating gate 110 and the substrate SB. The tunnel dielectric layer 150 may, for example, be used to tunnel the hot electrons when a corresponding voltage is applied to the memory element 100. For the rest of introduction about the tunnel dielectric layer 150, reference may be made to the above embodiment, which will not be repeated in the following.

The control gate structure 200 is, for example, disposed on the floating gate 110. The hot electrons may be tunneled to floating gate 110 by applying a voltage to the control gate structure 200, for example. Referring to FIGS. 2A and 2B, in this embodiment, a width WT of a top portion 200T of the control gate structure 200 in the direction X is greater than a width WB of a bottom portion 200B of the control gate structure 200 in the direction X. In detail, since the control gate structure 200 is disposed in the opening OP formed by the first recess R1 and the second recess R2, the control gate structure 200 may include the top portion 200T and the bottom portion 200B having different widths.

Referring to both FIGS. 2A and 2B, the control gate structure 200 in this embodiment includes the high-k dielectric layer 210, the bottom barrier layer 220, the work-function metal layer 232, the top barrier layer 234, and the low resistance material layer 236.

The high-k dielectric layer 210 is, for example, conformally disposed on the sidewall of the opening OP, and has, for example, a collar shape. In this embodiment, the material of the high-k dielectric layer 210 is hafnium oxide, but the disclosure is not limited thereto. For the rest of introduction about the high-k dielectric layer 210, reference may be made to the above embodiment, which will not be repeated in the following.

The bottom barrier layer 220 is, for example, conformally disposed on the high-k dielectric layer 210, and has, for example, a collar shape. In this embodiment, the bottom barrier layer 220 includes the first bottom barrier layer 222 and the second bottom barrier layer 224. The material of the first bottom barrier layer 222 is titanium nitride, and the material of the second bottom barrier layer 224 is tantalum nitride. However, the disclosure is not limited thereto. For the rest of introduction about the bottom barrier layer 220, reference may be made to the above embodiment, which will not be repeated in the following.

The work-function metal layer 232 is, for example, disposed on the bottom barrier layer 220, and has, for example, a U-shaped shape. In this embodiment, the material of the work-function metal layer 232 is titanium aluminum, but the disclosure is not limited thereto. For the rest of introduction about the work-function metal layer 232, reference may be made to the above embodiment, which will not be repeated in the following.

The top barrier layer 234 is, for example, disposed on the work-function metal layer 232, and has, for example, a U-shaped shape. In this embodiment, the material of the top barrier layer 234 is the combination of titanium and titanium nitride, but the disclosure is not limited thereto. For the rest of introduction about the top barrier layer 234, reference may be made to the above embodiment, which will not be repeated in the following.

The low resistance material layer 236 is, for example, disposed on the top barrier layer 234, and is, for example, filled in the opening OP. In this embodiment, the material of the low resistance material layer 236 is aluminum, but the disclosure is not limited thereto. For the rest of introduction about the low resistance material layer 236, reference may be made to the above embodiment, which will not be repeated in the following.

In this embodiment, the work-function metal layer 232, the top barrier layer 234, and the low resistance material layer 236 may be formed into the metal gate 230, but the disclosure is not limited thereto.

The inter-gate oxide layer 130 is, for example, disposed between the floating gate 110 and the control gate structure 200. The inter-gate oxide layer 130 may be used, for example, to electrically insulate the floating gate 110 and the control gate structure 200 from each other. In this embodiment, the inter-gate oxide layer 130 includes the oxide-nitride-oxide (ONO) composite layer, but the disclosure is not limited thereto. For the rest of introduction about the inter-gate oxide layer 130, reference may be made to the above embodiment, which will not be repeated in the following.

The erase gate 120 is, for example, disposed on one side of the floating gate 110. The erase gate 120 may, for example, have a function of erasing the hot electrons stored in the floating gate 110. For the rest of introduction about the erase gate 120, reference may be made to the above embodiment, which will not be repeated in the following.

The word line 140 is, for example, disposed on the other side of the floating gate 110. A corresponding write operation or read operation may be performed on the memory element 100 by applying a write voltage or a read voltage to the word line 140, but the disclosure is not limited thereto. For the rest of introduction about the word line 140, reference may be made to the above embodiment, which will not be repeated in the following.

The spacer 160 is, for example, disposed on one side of the word line 140 away from the floating gate 110. In this embodiment, the spacer 160 is a portion of the dielectric layer IL2, but the disclosure is not limited thereto.

In this embodiment, the semiconductor structure 10 further includes the high voltage element 300 and the logic element 400.

The high voltage element 300 is, for example, disposed in the high voltage element area A2. In this embodiment, the high voltage element 300 is a transistor. For example, the high voltage element 300 includes the gate 302, the gate oxide layer 304, and the spacer 306. The gate oxide layer 304 is disposed between the gate 302 and the substrate SB, and the spacer 306 is disposed on both sides of the gate 302. However, the disclosure is not limited thereto. For the rest of introduction about the high voltage element 300, reference may be made to the above embodiment, which will not be repeated in the following.

The logic element 400 is, for example, disposed in the logic element area A3. In this embodiment, the logic element 400 is a transistor. For example, the logic element 400 includes the high-k dielectric layer 410, the bottom barrier layer 420, the metal gate 430, the sidewall 440, and a spacer 450. The high-k dielectric layer 410 is disposed on the substrate SB. The bottom barrier layer 420 is disposed on the high-k dielectric layer 410. The metal gate 430 is disposed on the bottom barrier layer 420. However, the disclosure is not limited thereto. The bottom barrier layer 420 includes, for example, the first bottom barrier layer 422 and the second bottom barrier layer 424. The metal gate 430 includes, for example, the work-function metal layer 432, the top barrier layer 434, and the low resistance material layer 436. The sidewall 440 is, for example, disposed on both sides of the high-k dielectric layer 410, the bottom barrier layer 420, and the metal gate 430. The spacer 450 is, for example, disposed on one side of the sidewall 440 away from the metal gate 430. For the rest of introduction about the logic element 400, reference may be made to the above embodiment, which will not be repeated in the following.

In this embodiment, the semiconductor structure 10 may further include the interconnection structure 500.

Referring to both FIGS. 2A and 2B, the interconnection structure 500 includes, for example, the dielectric layer IL4 and the conductive vias V. The conductive vias V are, for example, disposed in the dielectric layer IL4, and each, for example, penetrates through the dielectric layer IL4. In this embodiment, the conductive vias V include the conductive via V1, the conductive via V2, the conductive via V3, a conductive via V4, and a conductive via V5. The conductive via V1 is, for example, electrically connected to the control gate structure 200 of the memory element 100. The conductive via V2 is, for example, electrically connected to the gate 302 of the high voltage element 300. The conductive via V3 is, for example, electrically connected to the metal gate 430 of the logic element 400. The conductive via V4 is, for example, electrically connected to the erase gate 120 of the memory element 100. The conductive via V5 is, for example, electrically connected to the word line 140 of the memory element 100.

Based on the above, in the semiconductor structure and the manufacturing method thereof provided in the disclosure, by forming the control gate structure including the high-k dielectric layer and the metal gate in the memory element, compared to the conventional embedded flash, the writing efficiency of the memory element in the disclosure may be increased.

Furthermore, in the manufacturing method of the semiconductor structure provided in the disclosure, the high-k dielectric layer and the metal gate may be formed in the same process as the remaining film layers in the logic element area. That is, no additional processes are required to form the high-k dielectric layer and the metal gate. On this basis, the manufacturing method of the semiconductor structure in the disclosure does not require additional manufacturing costs.

What is claimed is:

1. A semiconductor structure, comprising:
a substrate; and
a memory element disposed on the substrate and comprising:
a floating gate disposed on the substrate;
a tunnel dielectric layer disposed between the floating gate and the substrate;
a control gate structure disposed on the floating gate, wherein the control gate structure comprises a high-k dielectric layer and a metal gate, and a width of a top portion of the control gate structure is greater than a width of a bottom portion of the control gate structure;
an inter-gate oxide layer disposed between the floating gate and the control gate structure;
an erase gate disposed on one side of the floating gate; and
a word line disposed on the other side of the floating gate.

2. The semiconductor structure according to claim 1, wherein the control gate structure further comprises:
a bottom barrier layer disposed on the high-k dielectric layer.

3. The semiconductor structure according to claim 2, wherein the metal gate comprises:
a work-function metal layer disposed on the bottom barrier layer;
a top barrier layer disposed on the work-function metal layer; and
a low resistance material layer disposed on the top barrier layer.

4. The semiconductor structure according to claim 2, wherein the bottom barrier layer comprises:
a first bottom barrier layer, wherein a material of the first bottom barrier layer comprises titanium nitride; and
a second bottom barrier layer disposed on the first bottom barrier layer, wherein a material of the second bottom barrier layer comprises tantalum nitride.

5. The semiconductor structure according to claim 1, further comprising:
a high voltage element and a logic element disposed on the substrate;
a first isolation structure disposed in the substrate and located between the high voltage element and the memory element; and
a second isolation structure disposed in the substrate and located between the logic element and the high voltage element.

6. A manufacturing method of a semiconductor structure, comprising:
forming a memory material layer on a substrate, wherein the memory material layer comprises a floating gate, an erase gate, a first oxide layer, a first nitride layer, a second oxide layer, a second nitride layer, and a third oxide layer;
forming a first recess in the memory material layer, wherein the first recess exposes a portion of the first nitride layer;
forming a second recess in the memory material layer, wherein the second recess overlaps the first recess to form an opening, and the second recess exposes a portion of the floating gate;
forming an inter-gate oxide layer in the opening;
forming a dummy gate structure comprising a high-k dielectric layer in the opening; and
replacing the dummy gate structure with a control gate structure comprising a metal gate to form a memory element,
wherein a width of a top portion of the control gate structure is greater than a width of a bottom portion of the control gate structure.

7. The manufacturing method of the semiconductor structure according to claim 6, wherein a step of forming the dummy gate structure in the opening comprises:
forming the high-k dielectric layer on a sidewall of the opening;
forming a bottom barrier layer on the high-k dielectric layer; and
forming a dummy gate on the bottom barrier layer.

8. The manufacturing method of the semiconductor structure according to claim 7, wherein the memory material layer further comprises a word line material layer, and in a step of forming the dummy gate on the bottom barrier layer, the word line material layer is patterned to form a word line.

9. The manufacturing method of the semiconductor structure according to claim 7, wherein a step of forming the bottom barrier layer on the high-k dielectric layer comprises:
forming a first bottom barrier layer on the high-k dielectric layer, wherein a material of the first bottom barrier layer comprises titanium nitride and
forming a second bottom barrier layer on the first bottom barrier layer, wherein a material of the second bottom barrier layer comprises tantalum nitride.

10. The manufacturing method of the semiconductor structure according to claim 7, wherein a step of replacing the dummy gate structure with the control gate structure comprising the metal gate comprises:
removing the dummy gate;
forming a work-function metal layer on the bottom barrier layer;
forming a top barrier layer on the work-function metal layer; and
forming a low resistance material layer on the top barrier layer.
